(19) United States
(12) Patent Application Publication
(10) Pub. No.: US 2005/0270755 A1
(43) Pub. Date: Dec. 8, 2005

(54) Method for preventing pins of semiconductor package from short circuit during soldering

(75) Inventors: Ticky Tsai, Taipei (TW); Spring Liu, Taipei (TW)

Correspondence Address: Mr. Peter F. Corless;EDWARDS & ANGELL, LLP, 101 Federal Street, Boston, MA, 02110, US

(73) Assignee: Inventec Corporation

(21) Appl. No.: 10/861,009

(22) Filed: Jun. 4, 2004

(51) Int. Cl. H05K 7/02

(52) U.S. Cl. 361/760

(57) ABSTRACT

A method for preventing pins of a semiconductor package from short circuit during soldering is provided. The pins are soldered to a circuit board. At least one solder-mask area is formed on the circuit board or the pins, with a solder mask material being disposed on the solder-mask area. When the pins are soldered to the circuit board via a solder material, the solder material flashing to the solder-mask area is prevented to cause electrical connection between the adjacent pins, thereby preventing the pins from short circuit due to solder flash during the soldering process.

### FIELD OF THE INVENTION

The present invention relates to soldering methods, and more particularly, to a method for preventing pins of a semiconductor package from short circuit during soldering.

### BACKGROUND OF THE INVENTION

With the rapid growth of development of science and technology, functionality of semiconductor packages becomes stronger and volumes thereof are getting smaller. In response, the number of pins of a semiconductor package is greatly increased, while a pitch between the adjacent pins is decreased, making the pins arranged in a high density.

However, in the conventional technology, when the pins are soldered to a circuit board, there is no appropriate method for preventing the adjacent pins from electrical contact due to solder flash during a soldering process. As a result, the semiconductor package is subject to short circuit, and even worse, the circuit board would be damaged.

Referring to FIG. 1 showing a pin through hole (PTH) semiconductor package 100 having a plurality of pins 120. This PTH semiconductor package 100 may be one selected from the group consisting of dual in-line package (DIP), shrink DIP (SDIP), skinny DIP (SK-DIP), single in-line package (SIP), zig-zag in-line package (ZIP), and pin grid array (PGA) package. The semiconductor package 100 is mounted to a circuit board 110 by inserting and soldering the pins 120 of the semiconductor package 100 to corresponding through holes 130 formed in the circuit board 110. However, during the soldering process, a solder material 140 is apt to go upwardly in a direction M shown in FIG. 1 through the through holes 130 to a surface of the circuit board 110, thus resulting in solder flash. In case the adjacent pins 120 are electrically connected to each other via the flashed solder material 140, the semiconductor package 100 is short-circuited.

Referring to FIGS. 2 and 3 showing a surface mount technology (SMT) semiconductor package 200 having a plurality of pins 220. This SMT semiconductor package 200 may be one selected from the group consisting of small out-line package (SOP), quad flat package (QFP), headless chip carrier (LCC), plastic leadless chip carrier (PLCC) package, small out-line j-lead (SOJ) package, ball grid array (BGA) package, tape automated bonding (TAB) package, and chip scale package (CSP). The semiconductor package 200 is mounted to a circuit board 210 by soldering the pins 220 of the semiconductor package 200 to the circuit board 210 via a solder material 240. Due to a small pitch between the adjacent pins 220, the solder material 240 is apt to flash between adjacent pins 220, making the adjacent pins 220 electrically connected to each other and short-circuited. Similarly referring to FIG. 4, a BGA package 300 with its solder balls 340 being soldered to a circuit board 310 is also easily subject to solder flash. Referring to FIG. 5, even if there are solder pads 310 formed on the circuit board 310, the solder flash is hard to be effectively prevented.

Therefore, the problem to be solved here is to provide an improved method for preventing pins of a semiconductor package from solder flash and short circuit.

### SUMMARY OF THE INVENION

An objective of the present invention is to provide a method for preventing pins of a semiconductor package from short circuit during soldering, which is easily carried out.

In accordance with the above and other objectives, the present invention proposes a method for preventing pins of a semiconductor package from short circuit during soldering, wherein the pins are soldered to a circuit board. This method comprises the steps of: providing at least one contact area on the circuit board, for allowing at least one of the pins to be connected to the contact area; providing at least one bonding area outwardly around the contact area, for accommodating a solder material for soldering the at least one pin to the contact area; and providing at least one solder-mask area outwardly around the bonding area, with a solder mask material being disposed on the solder-mask area. The contact area may be shaped as a circle, rectangle, or any other geometric shape; the bonding area and solder-mask area may be respectively shaped as a circular ring, rectangular ring or any other geometric shape. The solder material is preferably tin. The solder mask material can be a white paint or green paint, and is disposed on the solder-mask area via a spraying, coating or printing technique. The semiconductor package may be a pin through hole (PTH) package such as dual in-line package (DIP), shrink DIP (SDIP), skinny DIP (SK-DIP), single in-line pack (SIP), zig-zag in-line package (ZIP) or pin grid array (PGA) package; or a surface mount technology (SMT) package such as small out-line package (SOP), quad flat package (QFP), leadless chip carrier (LCC) package, plastic leadless chip carrier (PLCC) package, small out-line j-lead (SOJ) package, ball grid array (BGA) package, tape automated bonding (TAB) package or chip scale package (CSP).

In case the semiconductor package is a PTH package, the effect of preventing pins of the semiconductor package from short circuit during soldering can be achieved by a method according to another preferred embodiment for use with a circuit board having through holes to be soldered to the pins. This method comprises the steps of: providing a solder-mask area at a predetermined position on each of at least a portion of the pins, with a solder mask material being disposed on the solder-mask area; and inserting the pins to the through holes of the circuit board, and allowing at least a portion of the solder-mask area to be located above a surface of the circuit board. The solder-mask area can be formed on one of any two adjacent pins. Alternatively, the solder-mask area may be provided on each of the pins. When the pins are engaged with the through holes of the circuit board, a lower edge of the solder-mask area can be flush with the surface of the circuit board or slightly lower in elevation than the surface of the circuit board.

The above method for preventing pins of a semiconductor package from short circuit during soldering yields significant advantages, for example comprising simple processes to be easily implemented, having low cost, and suitable for batch type fabrication of semiconductor packages.

### BRIEF DESCRIPTION OF THE DRAWINGS

The present invention can be more fully understood by reading the following is detailed description of the preferred embodiments, with reference made to the accompanying drawing wherein:

FIGS. 1-5 (PRIOR ART) are schematic diagrams respectively showing soldering of a conventional semiconductor package;

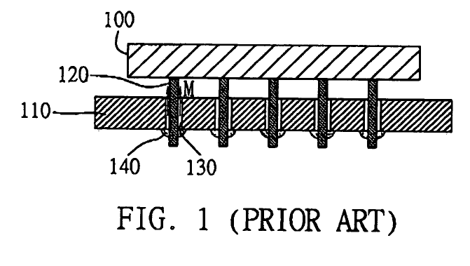

FIG. 6 is a schematic diagram of a circuit board used with a method for preventing pins of a semiconductor package from short circuit during soldering in accordance with a first preferred embodiment of the present invention;

FIG. 7 is a schematic diagram of a circuit board used with the method for preventing pins of a semiconductor package from short circuit during soldering in accordance with a second preferred embodiment of the present invention;

FIGS. 8-10 are schematic diagrams showing procedural steps of the method for preventing pins of a semiconductor package from short circuit during soldering in accordance with a third preferred embodiment of the present invention; and

FIG. 11 is a schematic diagram of a semiconductor package used with the method for preventing pins from short circuit during soldering in accordance with a fourth preferred embodiment of the present invention.

### DETAILED DESCRIPTION OF THE PREFERRED EMBODIMENTS

In particular, for clearly and compactly illustrating technical features of a method for preventing pins of a semiconductor package from short circuit during soldering proposed in the present invention, only essential elements and components related to the present invention are shown in the drawings. It should be understood that the structure of and connection between the elements and components are more complicated practically, and the number of the elements and components varies for different type semiconductor packages.

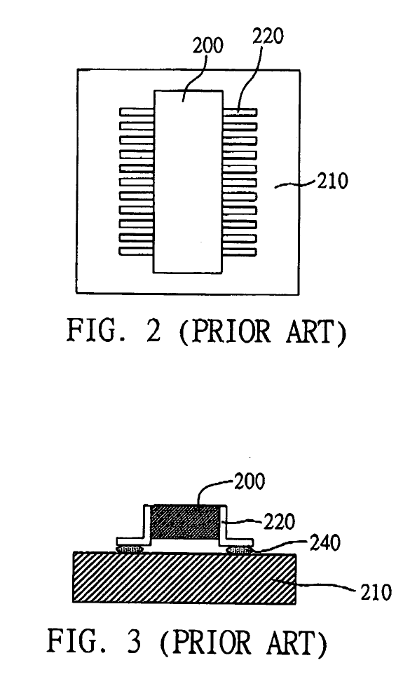

Referring to FIG. 6 showing a circuit board 10 used with the method for preventing pins from short circuit in accordance with a first preferred embodiment of the present invention. This circuit board 10 is defined with a plurality of predetermined positions for respectively connecting pins of a semiconductor package. Each of the predetermined positions comprises, outward from the center thereof in sequence, a contact area 12, a bonding area 14, and a solder-mask area 16. The suitable semiconductor package may be a pin through hole (PTH) semiconductor package such as dual in-line package (DIP), shrink DIP (SDIP), skinny DIP (SK-DIP), single in-line package (SIP), zig-zag in-line package (ZIP) or pin grid array (PGA) package; or a surface mount technology (SMT) semiconductor package such as small out-line package (SOP), quad flat package (QFP), leadless chip carrier (LCC) package, plastic leadless chip carrier (PLCC) package, small out-line j-lead (SOJ) package, ball grid array (BGA) package, tape automated bonding (TAB) package or chip scale package (CSP). The contact area 12 is to be connected to the corresponding pin of the semiconductor package, which is the area of the circuit board 10 to be in directly contact with the pin of the semiconductor package. In FIG. 6, the contact area 12 is preferably shaped as, for example, a circle. The bonding area 14 is located outwardly around the contact area 12 for accommodating a solder material such as tin that is to securely solder the corresponding pin of the semiconductor package to the contact area 12 of the circuit board 10. In FIG. 6, the bonding area 14 is preferably shaped as, for example, a circular ring. The solder-mask area 16 is located outwardly around the bonding area 14, for allowing a solder mask material such as white paint or green paint to be sprayed, coated or printed thereon, so as to prevent flash of the solder material between the adjacent pins during soldering the pins of the semiconductor package to the circuit board 10, thereby avoiding undesirable electrical connection and short circuit between the adjacent pins, as well as eliminating damage to the semiconductor package and the circuit board 10. In FIG. 6, the solder-mask area 16 is preferably shaped as, for example, a circular ring.

It should be understood that, in case the semiconductor package is a PTH package, the contact area 12 is a through hole where the pin is inserted.

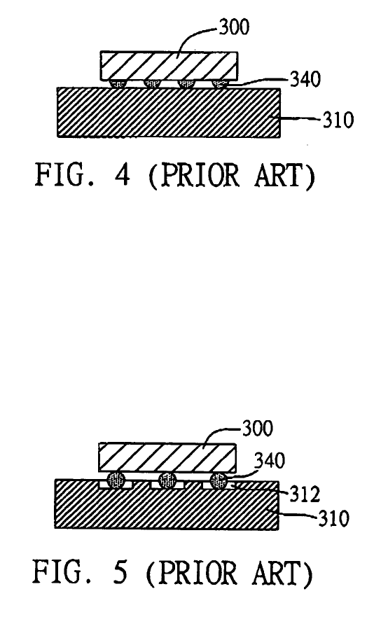

Referring to FIG. 7 showing a circuit board 10′ used with the method for preventing pins from short circuit in accordance with a second preferred embodiment of the present invention. Similarly, this circuit board 10′ is defined with a plurality of predetermined positions for respectively connecting pins of a semiconductor package. Each of the predetermined positions comprises, outward from the center thereof in sequence, a contact area 12′, a bonding area 14′, and a solder-mask area 16′. This embodiment differs from the above first embodiment in that, the contact area 12′ is preferably shaped as a rectangle or square, and the bonding area 14′ and solder-mask area 16′ are each preferably shaped as a rectangular ring.

Similarly, in case the semiconductor package is a PTH semiconductor package, the contact area 12′ should be a through hole where the pin is inserted.

The contact areas 12, 12′, bonding areas 14, 14′, and solder-mask areas 16, 16′ in the above first and second embodiments are not limit to be the shapes (such as circle or rectangle) shown in the drawings, but can have any other suitable shapes corresponding to the shape of the pins of the semiconductor package; or the shapes of the contact areas 12, 12′, bonding areas 14, 14′, and solder-mask areas 16, 16′ can be combinations of circle, rectangle and any other shapes, as long as a set of the corresponding contact area 12, 12′, bonding area 14, 14′, and solder-mask area 16, 16′ are arranged in sequence from inside to outside, such that the effect of preventing short circuit of the pins of the semiconductor package during soldering can be achieved.

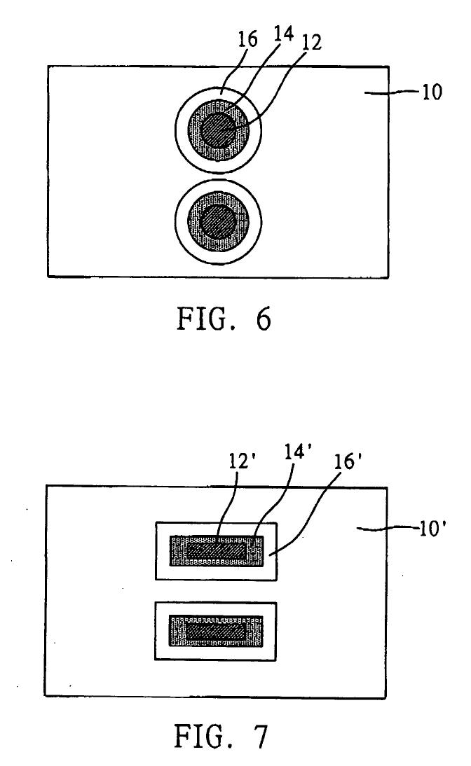

FIGS. 8-10 show the procedural steps of the method for preventing pins of a semiconductor package 20 from short circuit during soldering in accordance with a third preferred embodiment of the present invention, wherein the semiconductor package 20 is a PTH package having a plurality of pins 22. Referring to FIG. 8, a solder-mask area 24 is provided at a predetermined position on each of the pins 22 by spraying, coating or printing a solder mask material such as white paint or green paint thereon. Referring to FIG. 9, when the pins 22 of the semiconductor package 20 are inserted to corresponding through holes 32 of a circuit board 30, a lower edge of the solder-mask area 24 on each of the pins 22 is flush with a surface of the circuit board 30; alternatively referring to FIG. 10, the lower edge of the solder-mask area 24 on each of the pins 22 can be slightly lower in elevation than the surface of the circuit board 30. This circuit board 30 can be structured similarly to the circuit board 10, 10′ shown in FIG. 6 or 7. This arrangement can effectively prevent short circuit of the pins 22 of the semiconductor package during the soldering process. In particular, even if a solder material 40 such as tin goes upwardly through the through hole 32 to the surface of the circuit board 30 and flashes on the circuit board 30, the adjacent pins 22 would not be electrically connected to each other via the solder flash due to the provision of the solder mask material on the solder-mask areas 24, such that the pins 22 are protected from being electrically connected and short-circuited with each other, and the semiconductor package 20 and the circuit board 30 can be prevented from being damaged.

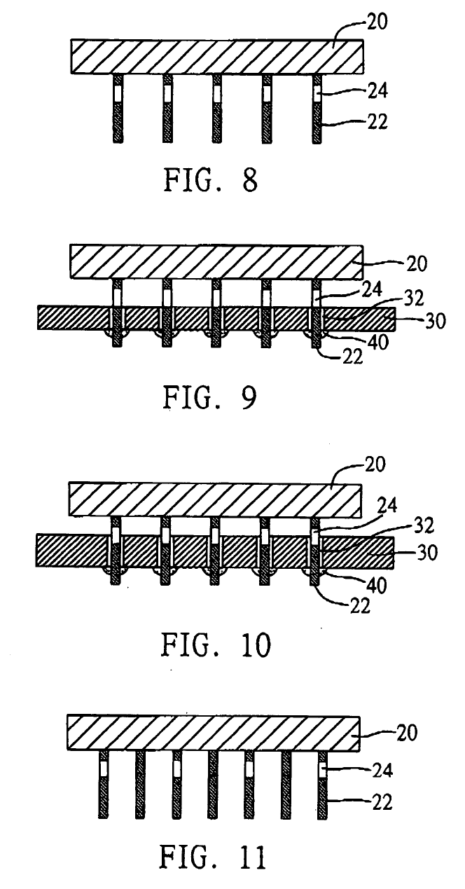

FIG. 11 shows a semiconductor package 20 used with the method for preventing pins from short circuit during soldering in accordance with a fourth preferred embodiment of the present invention. This embodiment differs from the above third embodiment in that, solder-mask areas 24 are provided on a portion of pins 22 of the semiconductor package 20 in a manner that only one of any two adjacent pins 22 is formed with the solder-mask area 24. As shown in FIG. 11, a pin 22 having the solder-mask area 24 is adjacent to another pin 22 not having the solder-mask area. This arrangement can also protect the pins 22 from being electrically connected and short-circuited with each other during the process of soldering the pins 22 to a circuit board (not shown), as well as eliminate the damage to the semiconductor package 20 and the circuit board.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method for preventing pins of a semiconductor package from short circuit during soldering, with the pins being soldered to a circuit board, the method comprising the steps of:
providing at least one contact area on the circuit board, for allowing at least one of the pins to be connected to the contact area;
providing at least one bonding area outwardly around the contact area, for accommodating a solder material for soldering the at least one pin to the contact area; and
providing at least one first solder-mask area outwardly around the bonding area, with a solder mask material being disposed on the first solder-mask area.

2. The method of claim 1, wherein the solder mask material is disposed on the first solder-mask area by a spraying coating or printing technique.

3. The method of claim 1, wherein the solder mask material is a white paint or a green paint.

4. The method of claim 1, wherein the semiconductor package is a pin though hole (PTH) package or a surface mount technology (SMT) package.

5. The method of claim 4, wherein if the semiconductor package is a PTH package, the contact area comprises a through bole.

6. The method of claim 1, further comprising providing a second solder-mask area at a predetermined position on each of at least a portion of the pins, with the solder mask material being disposed the second solder-mask area.

7. The method of claim 6, wherein a lower edge of the second solder-mask area is flush with a surface of the circuit board.

8. The method of claim 6, wherein a lower edge of the second solder-mask area is slightly lower in elevation than a surface of the circuit board.

9. The method of claim 6, wherein the second solder-mask area is formed on one of any two adjacent pins.

10. The method of claim 6, wherein the second solder-mask area is provided on each of the pins.

11. The method of claim 10, wherein a lower edge of the second solder-mask area is flush with a surface of the circuit board.

12. The method of claim 10, wherein a lower edge of the second solder-mask area is slightly lower in elevation than a surface of the circuit board.

13. A method for preventing pins of a semiconductor package from short circuit during soldering, for use with a circuit board having through holes to be soldered to the pins, the method comprising the steps of:
providing a solder-mask area at a predetermined position on each of at least a portion of the pins, with a solder mask material being disposed on the solder-mask area; and
inserting the pins to the through boles of the circuit board, and allowing at least a portion of the solder-mask area to be located above a surface of the circuit board.

14. The method of claim 13, wherein the semiconductor package is a pin through hole (PTH) package.

15. The method of claim 13, wherein the solder-mask area is formed on one of any two adjacent pins.

16. The method of claim 13, wherein a lower edge of the solder-mask area is flush with the surface of the circuit board.

17. The method of claim 13, wherein a lower edge of the solder-mask area is slightly lower in elevation than the surface of the circuit board.

18. The method of claim 13, wherein the solder-mask area is formed on each of the pins.

19. The method of claim 18, wherein a lower edge of the solder-mask area is flush with the surface of the circuit board.

20. The method of claim 18, wherein a lower edge of the solder-mask area is slightly lower in elevation than the surface of the circuit board.
